(19) United States
(12) Patent Application Publication
(10) Pub. No.: US 2006/0053355 A1
(43) Pub. Date: Mar. 9, 2006

(54) Semiconductor integrated circuit device

(75) Inventor: Hideharu Ozaki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/220,720

(22) Filed: Sep. 8, 2005

(30) Foreign Application Priority Data
Sep. 9, 2004 (JP) 262736/2004

(51) Int. Cl. G01R 31/28

(52) U.S. Cl. 714/724

(57) ABSTRACT

A semiconductor integrated circuit device has: a plurality of macro circuits; and a plurality of decoders configured to supply a test enable signal to the plurality of macro circuits. Each decoder is provided with respect to a corresponding predetermined number of macro circuits of the plurality of macro circuits.

### BACKGROUND OF THE INVENTION

1. Field of the Invention

The present invention generally relates to a semiconductor integrated circuit device. In particular, the present invention relates to a semiconductor integrated circuit device having a test circuit used for testing a macro circuit.

2. Description of the Related Art

FIG. 1 is a diagram showing a configuration of a general semiconductor integrated circuit device. The semiconductor integrated circuit device 100 has a plurality of macro circuits 110. The macro circuit 110 is, for example, a RAM (Random Access Memory). In the semiconductor integrated circuit device 100, it is necessary to set each of the macro circuits 110 to a test enable status in order to test the each macro circuit 110. For controlling statuses of the macro circuits 110, control signals may be input to respective macro circuits 110 from the outside through a test macro select pin 130. Here, in order to reduce the number of control signals, a decoder 120 is generally employed as shown in FIG. 1. The decoder 120 is connected to the plurality of macro circuits 110 through a plurality of test enable signal interconnections 140, respectively.

FIG. 2 is a block diagram schematically showing an expanded circuit configuration of the semiconductor integrated circuit device shown in FIG. 1. Input to the test macro select pin 130 is a “test macro select signal SEL” which specifies a test target macro circuit 110t to be tested from the plurality of macro circuits 110.

The test macro select signal SEL is, for instance, a 6-bit signal. The decoder 120 connected to the test macro select pin 130 receives the 6-bit test macro select signal SEL. Then, one of the plurality of test enable signal interconnections 140 corresponding to the test macro select signal SEL is selected by the decoder 120. A signal supplied to the selected one test enable signal interconnection 140 is a “test enable signal TEN”, which is input to the test target macro circuit 110t. As a result, the test target macro circuit 110t is set to the test enable status.

The above-described configuration is disclosed, for example, in Japanese Laid-open Patent Application No. JP-Hei-06-317633.

### SUMMARY OF THE INVENTION

The present invention has recognized the following points. In the conventional semiconductor integrated circuit device, as shown in FIG. 1, the decoder 120 is arranged at the center of an IC chip. It is necessary to provide the test enable signal interconnections 140 between the decoder 120 located around the center and respective of 36 macro circuits 110 distributed over an entire area of the IC chip. Thus, there is a problem in that area overhead due to the 36 test enable signal interconnections 140 is increased. Such a problem becomes bigger as the number of macro circuits included in the IC chip

Particularly, in a “master slice method” as one method of developing a semiconductor integrated circuit device, a large number of macro circuits are arranged over an entire area of a chip, and hence the above-mentioned problem becomes conspicuous. Also, a technique referred to as “Structured ASIC (Application Specific Integrated Circuit)” has been recently proposed as one type of the master slice method. According to the structured ASIC, for example, a multi-layer interconnection formed in six interconnection layers is used. The lower three layers of the six interconnection layers are provided as a “base layer” which is used in common, while the upper three layers are provided as a “customize interconnection layer”. In the base layer, the plurality of macro circuits are manufactured beforehand. On the other hand, in the customize interconnection layer, interconnections are formed in accordance with specific circuits requested by a client. It is thus possible to reduce development/production TAT and to reduce cost of manufacturing. An important point with regard to the structured ASIC is flexibility necessary for realizing the specific circuits requested by a client. To ensure the flexibility, a large number of macro circuits are previously embedded in the base layer. That is why, the above-mentioned problem is conspicuous in the structured ASIC.

It is desired to reduce the area for the interconnections in the semiconductor integrated circuit device.

In an aspect of the present invention, a semiconductor integrated circuit device has: a plurality of macro circuits; and a plurality of decoders configured to supply a test enable signal to the plurality of macro circuits. Each decoder is provided with respect to a corresponding predetermined number of macro circuits of the plurality of macro circuits.

Each decoder and the corresponding predetermined number of macro circuits configure a unit circuit. Each decoder is connected with the corresponding predetermined number of macro circuits. One of the plurality of decoders supplies the test enable signal to one of the corresponding predetermined number of macro circuits.

In the device thus constructed, one decoder is provided for every unit circuit which includes the predetermined number of macro circuits. Thus, the length of a test enable signal interconnection connecting between a macro circuit and a decoder can be shortened. Therefore, the area necessary for total interconnections in an IC chip can be reduced on the whole.

Moreover, since the length of the test enable signal interconnection is shortened, it is possible to suppress the number of buffers as compared with the conventional technique. It is therefore possible not only to decrease the circuit area but also to reduce the cost of manufacturing. Furthermore, the number of test enable signal interconnections connected to one decoder is decreased as compared with the conventional technique. It is therefore possible to relieve the congestion of the interconnections around the decoder.

The above-mentioned effects become more remarkable as the number of macro circuits included in the semiconductor integrated circuit device is increased. In the structured ASIC, as described above, the flexibility enough to realize the specific circuits requested by the client is required. To meet the requirement, a large number of macro circuits are previously formed in the base layer. Therefore, the present invention yields the remarkable effects especially when applied to the structured ASIC.

According to the present invention, it is possible to reduce the area for the interconnections in the semiconductor integrated circuit device. Moreover, the number of buffers can be suppressed. It is also possible to relieve the congestion of the interconnections.

### BRIEF DESCRIPTION OF THE DRAWINGS

The above and other objects, advantages and features of the present invention will be more apparent from the following description taken in conjunction with the accompanying drawings, in which:

FIG. 1 is a diagram schematically showing a configuration of a conventional semiconductor integrated circuit device;

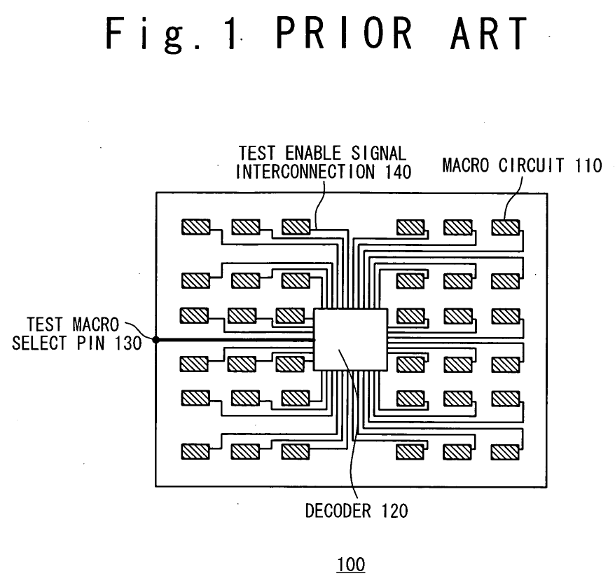

FIG. 2 is a block diagram schematically showing an expanded circuit configuration of the semiconductor integrated circuit device shown in FIG. 1;

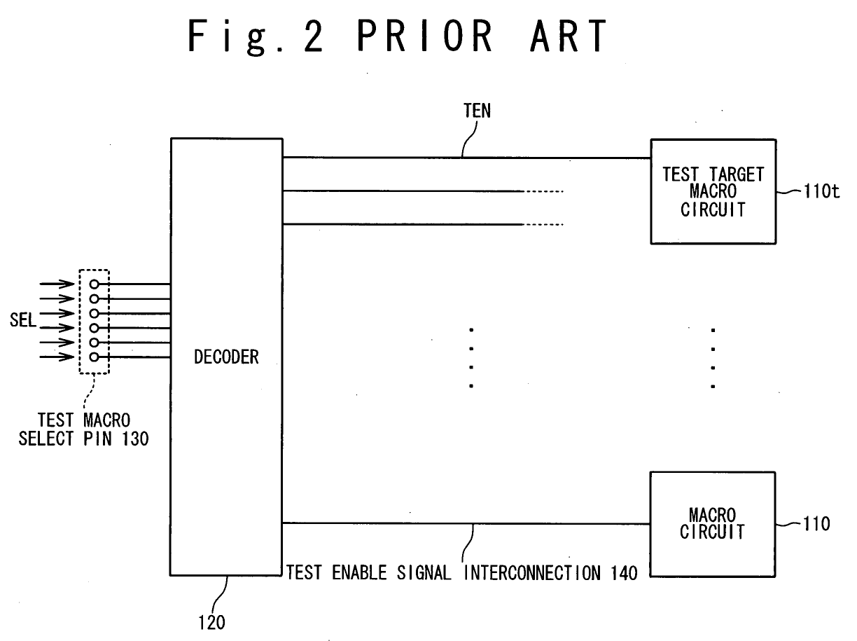

FIG. 3 is a diagram schematically showing a configuration of a semiconductor integrated circuit device according to an embodiment of the present invention;

FIG. 4 is a block diagram schematically showing a configuration of the semiconductor integrated circuit device according to the embodiment of the present invention;

FIG. 5 is a schematic diagram showing an example of a macro circuit according to the embodiment of the present invention; and

FIG. 6 is a schematic diagram showing another example of a macro circuit according to the embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

(Configuration)

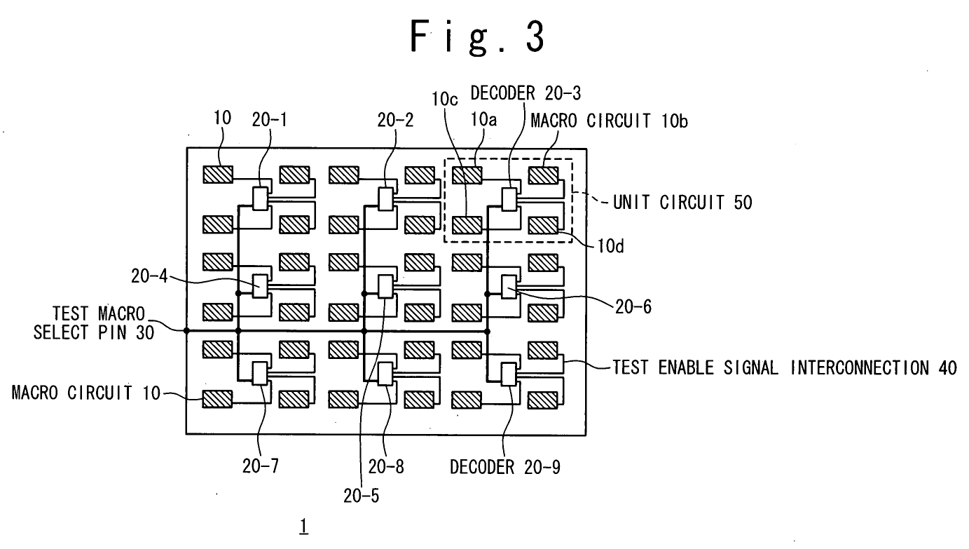

FIG. 3 is a diagram schematically showing a configuration of a semiconductor integrated circuit device 1 according to an embodiment of the present invention. The semiconductor integrated circuit device 1 has a plurality of macro circuits 10, a plurality of decoders 20, and a test macro select pin 30. For example, as shown in FIG. 3, the semiconductor integrated circuit device 1 has thirty-six macro circuits 10 and nine decoders 20-1 to 20-9. The plurality of decoders 20 are connected to the test macro select pin 30 in common. Also, each of the decoders 20 is connected to a corresponding predetermined number of macro circuits 10 of the 36 macro circuits 10. For instance, as shown in FIG. 3, one decoder 20 is connected to four macro circuits 10 through respective of four test enable signal interconnections 40. It should be understood that the number of macro circuits 10 connected to one decoder 20 can be different from the number of macro circuits 10 connected to another decoder 20.

The macro circuit 10 includes a RAM. The plurality of macro circuits 10 are arranged over an entire area of an IC chip. Particularly, in a case when the semiconductor integrated circuit device 1 is a “structured ASIC”, the plurality of macro circuits 10 are previously formed in a “base layer” of the structured ASIC. The base layer is constituted, for example, by the lower three layers of six interconnection layers. In the upper three layers (customize interconnection layer), customize interconnections are formed in accordance with specific circuits requested by a client. Therefore, flexibility enough to realize the specific circuits requested by the client is necessary with respect to the structured ASIC. To ensure the flexibility, a large number of macro circuits 10 are previously formed in the above-mentioned base layer.

In the base layer of the structured ASIC, a certain “unit structure” may be repeatedly arranged in an array form. In the above-described example, four macro circuits 10 and one decoder 20 configure a unit structure (referred to as a “unit circuit 50” hereinafter). For example, a unit circuit 50 indicated by a dashed line in FIG. 3 includes one decoder 20-3 and four macro circuits 10a to 10d. In the unit circuit 50, the decoder 20-3 is connected to four macro circuits 10a to 10d through respective of four test enable signal interconnections 40. In the semiconductor integrated circuit device 1, such a unit circuit 50 is arranged repeatedly in an array form. A plurality of unit circuits 50 are connected to the test macro select pin 30, i.e., the decoder 20 included in each unit circuit 50 is connected to the test macro select pin 30.

According to the present embodiment, as described above, each of the plurality of decoders 20 is provided with respect to the corresponding predetermined number of macro circuits 10. For example, the decoder 20-3 is provided for four macro circuits 10a to 10d. Also, each decoder 20 is arranged in the vicinity of the predetermined number of macro circuits 10. One decoder 20 and a predetermined number of macro circuits 10 connected to the one decoder 20 preferably configure one unit circuit 50.

(Operation)

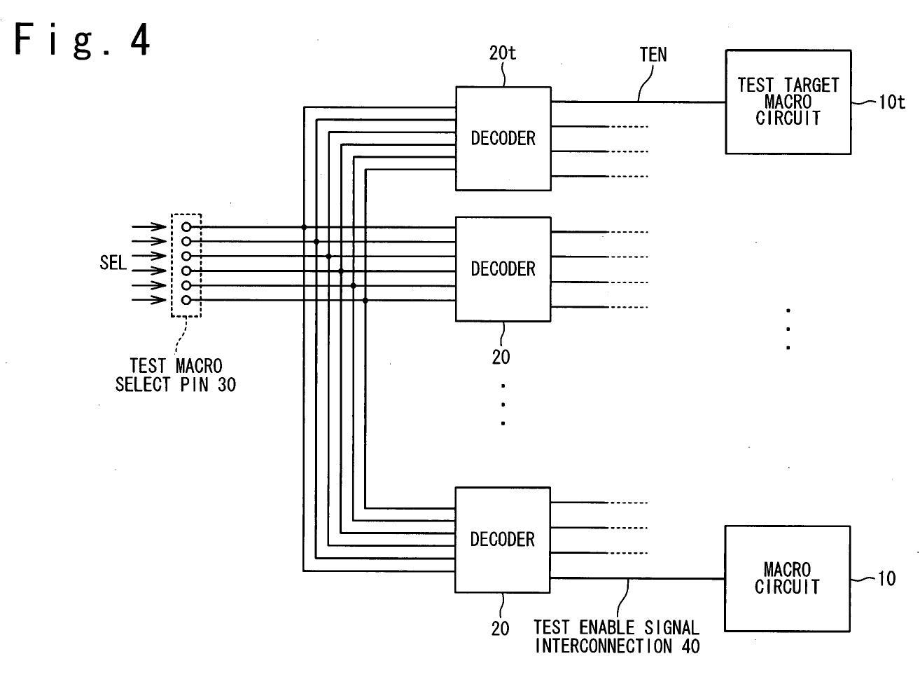

FIG. 4 is a block diagram schematically showing an expanded circuit configuration of the semiconductor integrated circuit device 1 shown in FIG. 3. A test target macro circuit 10t is a macro circuit to be tested, which is specified from the plurality of macro circuits 10 by a “test macro select signal SEL”. The test macro select signal SEL is, for example, a 6-bit signal, and is capable of specifying 64 macro circuits 10 individually. The test macro select signal SEL is input to the test macro select pin 30.

Each decoder 20 receives the test macro select signal SEL from the test macro select pin 30. As a result of the decoding, one of the plurality of test enable signal interconnections 40 connected with a decoder 20 is selected in accordance with the test macro select signal SEL. For example, selected in FIG. 4 is one of four test enable signal interconnections 40 which are connected to a decoder 20t. A macro circuit 10 connected with the selected one test enable signal interconnection 40 is the above-mentioned test target macro circuit 10t, and a “test enable signal TEN” is supplied to the test target macro circuit 10t. Accordingly, the test target macro circuit 10t is set to the test enable status. As described above, the decoder 20 supplies the test enable signal TEN to any one of the predetermined number of macro circuits 10 based on the test macro select signal SEL.

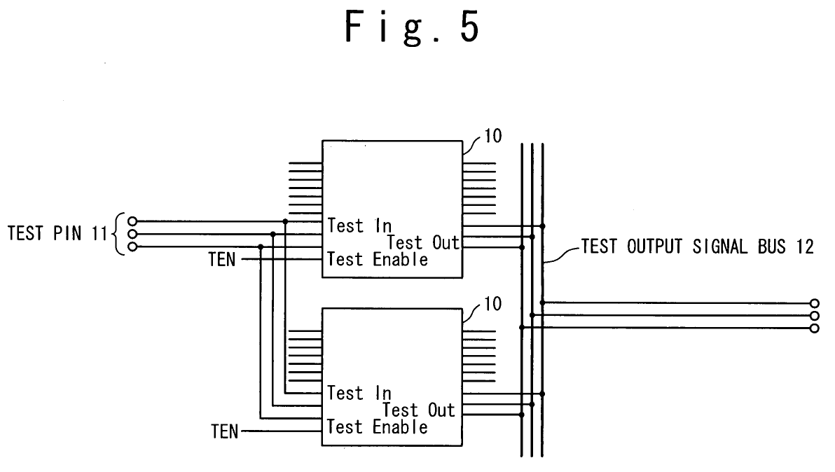

FIG. 5 is a schematic diagram showing one example of the test macro circuit 10 according to the present embodiment. The macro circuit 10 has a pin “TestIn” for receiving a test signal, a pin “TestOut” for outputting a test output signal indicative of a test result, and a pin “TestEnable” for receiving the above-described test enable signal TEN. The pin TestIn of each macro circuit 10 is connected to a test pin 11, whereas the pin TestOut of each macro circuit 10 is connected to a test output signal bus 12. The testings of respective of the macro circuits 10 are carried out individually. That is to say, a single test enable signal TEN is input to a certain macro circuit 10, and thus the certain macro circuit 10 is set to the test enable status. After that, the test signal is input to the macro circuit 10 under test enable status from the test pin 11, and then the test output signal is output from the macro circuit 10 to the test output signal bus 12.

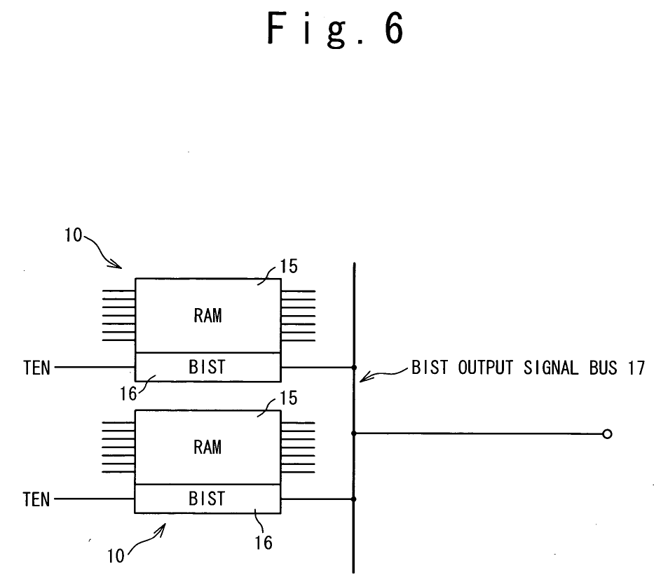

FIG. 6 is a schematic diagram showing another example of the macro circuit 10 according to the present embodiment. The macro circuit 10 has a RAM 15 and a BIST (Built-in Self Test) circuit 16 which is used for testing the RAM 15. The BIST circuit 16 includes a self-testing circuit for testing the RAM 15. The testings of respective of the RAMs 15 are carried out individually. That is to say, a single test enable signal TEN is input to a certain BIST circuit 16. Accordingly, the macro circuit 10 is set to the test enable status (BIST mode). In response to the test enable signal TEN, the BIST circuit 16 carries out a test of the RAM 15 by operating the foregoing self-testing circuit. Then, a BIST output signal indicative of the test result is output to a BIST output signal bus 17 which is shared by the plurality of macro circuits 10.

(Effects)

According to the present embodiment, as described above, one decoder 20 is provided for every unit circuit 50 which includes the predetermined number of macro circuits 10. Thus, the length of each test enable signal interconnection 40 connecting between a macro circuit 10 and a decoder 20 can be shortened. In other words, the area of the thirty-six test enable signal interconnections 40 in the foregoing example is reduced. Although interconnections between the test macro select pin 30 and respective of the decoders 20 are required, the area necessary for total interconnections in the IC chip can be reduced on the whole.

Moreover, since the length of each test enable signal interconnection 40 is shortened, it is possible to suppress the number of buffers necessary for dealing with the delay and the voltage drop, as compared with the conventional technique. It is therefore possible not only to decrease the circuit area but also to reduce the cost of manufacturing. Furthermore, the number of test enable signal interconnections 40 connected to one decoder 20 is decreased as compared with the conventional technique. It is therefore possible to relieve the congestion of the interconnections in the vicinity of the decoder 20.

The above-mentioned effects become more remarkable with increasing the circuit scale. In other words, as the number of macro circuits 10 included in the semiconductor integrated circuit device 1 is increased and as the macro circuits 10 are dispersed over a wider area of a chip, the above-mentioned effects become more conspicuous. In the structured ASIC, as described above, the flexibility enough to realize the specific circuits requested by the client is required. To meet the requirement, a large number of macro circuits 10 are previously formed in the base layer. Therefore, the present invention yields the remarkable effects especially when applied to the structured ASIC.

In the structured ASIC, a plurality of unit structures are often arranged in the base layer. It is preferable that the above-mentioned unit circuit 50 according to the present embodiment is used as the unit structure in the structured ASIC. In this case, the plurality of macro circuits 10 and test enable signal interconnections 40 are placed and arranged systematically. Therefore, the congestion of the interconnections is relieved. The plurality of unit circuits 50 are arranged in the base layer, for example, in an array form. It should be noted that in the case of the structured ASIC, the testings of the macro circuits 10 are possible even before the customize interconnections are formed in the customize interconnection layer.

It is apparent that the present invention is not limited to the above embodiment, and that may be modified and changed without departing from the scope and spirit of the invention.

What is claimed is:

1. A semiconductor integrated circuit device comprising:
a plurality of macro circuits; and
a plurality of decoders configured to supply a test enable signal to said plurality of macro circuits,
wherein each of said plurality of decoders is provided with respect to a corresponding predetermined number of macro circuits of said plurality of macro circuits.

2. The semiconductor integrated circuit device according to claim 1,
wherein said each decoder is connected with said corresponding predetermined number of macro circuits, and one of said plurality of decoders supplies said test enable signal to one of said corresponding predetermined number of macro circuits.

3. The semiconductor integrated circuit device according to claim 2, further comprising a test macro select pin connected to said plurality of decoders in common,
wherein a select signal specifying a test target of said plurality of macro circuits is input to said plurality of decoders through said test macro select pin, and said one decoder supplies said test enable signal to said test target based on said select signal.

4. The semiconductor integrated circuit device according to claim 1,
wherein said each decoder and said corresponding predetermined number of macro circuits configure a unit circuit which is arranged repeatedly.

5. The semiconductor integrated circuit device according to claim 3,
wherein said each decoder and said corresponding predetermined number of macro circuits configure a unit circuit which is arranged repeatedly and is connected to said test macro select pin.

6. The semiconductor integrated circuit device according to claim 1,
wherein each of said plurality of macro circuits includes:
a memory; and
a BIST (Built-In Self Test) circuit for testing said memory,
wherein said BIST circuit carries out a test of said memory in response to said test enable signal.

7. The semiconductor integrated circuit device according to claim 1,
wherein said plurality of macro circuits are formed in a base layer of a structured ASIC.

8. A semiconductor integrated circuit device comprising:
a plurality of unit circuits; and
a test macro select pin connected to said plurality of unit circuits,
wherein each of said plurality of unit circuits includes:
a decoder connected to said test macro select pin; and
a plurality of macro circuits connected to said decoder,
wherein said decoder receives from said test macro select pin a select signal specifying a test target of said plurality of macro circuits, and supplies a test enable signal to said test target based on said select signal.

9. The semiconductor integrated circuit device according to claim 8,
wherein each of said plurality of macro circuits includes:
a memory; and
a BIST (Built-In Self Test) circuit for testing said memory,
wherein said BIST circuit carries out a test of said memory in response to said test enable signal.

10. The semiconductor integrated circuit device according to claim 8,
wherein said plurality of unit circuits are formed in a base layer of a structured ASIC.

11. A structured ASIC comprising:
a base layer; and
a plurality of unit circuits formed in said base layer,
wherein each of said plurality of unit circuits includes:
a decoder; and
a plurality of macro circuits connected to said decoder,
wherein said decoder supplies a test enable signal to any of said plurality of macro circuits.

12. The structured ASIC according to claim 11, further comprising a test macro select pin connected to said plurality of unit circuits,
wherein said decoder receives from said test macro select pin a select signal specifying a test target of said plurality of macro circuits, and supplies said test enable signal to said test target based on said select signal.
